(19) United States
(12) Patent Application Publication
(10) Pub. No.: US 2025/0028251 A1
(43) Pub. Date: Jan. 23, 2025

(54) LITHOGRAPHY SYSTEM AND RELATED METHODS FOR FORMING STRUCTURES OF DIFFERENT DEPTHS AND SHAPES

(71) Applicant: Applied Materials, Inc., Santa Clara, CA (US)

(72) Inventors: Thomas L. LAIDIG, Richmond, CA (US); Chi-Ming TSAI, San Jose, CA (US)

(21) Appl. No.: 18/714,792

(22) PCT Filed: Nov. 9, 2022
(86) PCT No.: PCT/US2022/049410

§ 371 Date: May 30, 2024

Related U.S. Application Data
(60) Provisional application No. 63/293,945, filed on Dec. 27, 2021.

(51) Int. Cl. G03F 7/00; G03F 7/20

(52) U.S. Cl. CPC G03F 7/70416; G03F 7/2022; G03F 7/7005; G03F 7/70391; G03F 7/70466

(57) ABSTRACT

A method is provided including directing a plurality of beams of radiation at a first area of a first layer on a substrate, each beam incident upon a different portion of a plurality of portions within the first area. Each portion has an area of a first size, the plurality of beams of radiation are directed at the first area based on a first pattern, the first pattern comprises a plurality of unit cells that include a plurality of on cells and a plurality of off cells, each unit cell has an area smaller than the first size, the plurality of on cells identify locations within the first area at which a beam of radiation of the plurality of beams of radiation is centrally focused, and the plurality of off cells identify locations within the first area at which no beam of radiation of the plurality of beams of radiation is centrally focused.

### BACKGROUND

### Field

Embodiments of the present disclosure generally relate to lithography systems and lithography methods. More specifically, embodiments described herein relate to lithography systems and methods for forming structures of varying dimensions (e.g., various depths) in less exposures, such as in a single pass.

### Description of the Related Art

Photolithography is widely used in the manufacturing of semiconductor devices, such as for back-end processing of semiconductor devices, and display devices, such as liquid crystal displays (LCDs). For example, large area substrates are often utilized in the manufacture of LCDs. LCDs, or flat panel displays, are commonly used for active matrix displays, such as computers, touch panel devices, personal digital assistants (PDAs), cell phones, television monitors, and the like. Generally, flat panel displays include a layer of liquid crystal material as a phase change material at each pixel, sandwiched between two plates. When power from a power supply is applied across or through the liquid crystal material, an amount of light passing through the liquid crystal material is controlled, i.e., selectively modulated, at the pixel locations enabling images to be generated on the display.

To form structures having different depths using conventional lithography systems, multiple passes of the substrate under the writable area of the lithography system are required. Multiple passes of the substrate under the writable area of a lithography system decreases throughput.

Accordingly, what is needed in the art is a lithography system and related methods to form structures having different depths without the throughput problems mentioned above.

### SUMMARY

In one embodiment, a method is provided. The method includes directing a plurality of beams of radiation at a first area of a first layer on a substrate, each beam incident upon a different portion of a plurality of portions within the first area. Each portion has an area of a first size, the plurality of beams of radiation are directed at the first area based on a first pattern, the first pattern comprises a plurality of unit cells that include a plurality of on cells and a plurality of off cells, each unit cell has an area smaller than the first size, the plurality of on cells identify locations within the first area at which a beam of radiation of the plurality of beams of radiation is centrally focused, and the plurality of off cells identify locations within the first area at which no beam of radiation of the plurality of beams of radiation is centrally focused.

In another embodiment, a method is provided. The method includes directing a first plurality of beams of radiation at a first area of a first layer on a substrate, each beam incident upon a different portion of a plurality of portions within the first area. The method further includes directing a second plurality of beams of radiation at a second area of the first layer on the substrate, each beam incident upon a different portion of a plurality of portions within the second area, wherein each portion in the first area and the second area has an area of a first size, the first plurality of beams of radiation are directed at the first area based on a first pattern, the second plurality of beams of radiation are directed at the second area based on a second pattern, the first pattern and the second pattern each comprise a plurality of unit cells that each include a plurality of on cells and a plurality of off cells, each unit cell in the first pattern and the second pattern has an area smaller than the first size, the plurality of on cells in the first pattern identify locations within the first area at which a beam of radiation of the first plurality of beams of radiation is centrally focused, the plurality of off cells in the first pattern identify locations within the first area at which no beam of radiation of the first plurality of beams of radiation is centrally focused, the plurality of on cells in the second pattern identify locations within the second area at which a beam of radiation of the second plurality of beams of radiation is centrally focused, and the plurality of off cells in the second pattern identify locations within the second area at which no beam of radiation of the second plurality of beams of radiation is centrally focused.

In another embodiment, a method is provided. The method includes directing a first plurality of beams of radiation at a first region of a first area of a first layer on a substrate, each beam in the first plurality of beams incident upon a different portion of a plurality of portions within the first region. The method further includes directing a second plurality of beams of radiation at a second region of the first area, each beam of the second plurality of beams incident upon a different portion of a plurality of portions within the second region, wherein each portion in the first region and the second region has an area of a first size, the second plurality of beams of radiation are directed at the first region of the first area based on a first pattern, the second plurality of beams of radiation are directed at the second region of the first area based on a second pattern, the first pattern and the second pattern each comprise a plurality of unit cells that include a plurality of on cells and a plurality of off cells, each unit cell in the first pattern and the second pattern has an area smaller than the first size, the plurality of on cells in the first pattern identify locations within the first region at which a beam of radiation of the first plurality of beams of radiation is centrally focused, the plurality of off cells in the first pattern identify locations within the first region at which no beam of radiation of the first plurality of beams of radiation is centrally focused, and the plurality of on cells in the second pattern identify locations within a second region at which a beam of radiation of the plurality of beams of radiation is centrally focused, and the plurality of off cells in the second pattern identify locations within the second region at which no beam of radiation of the second plurality of beams of radiation is centrally focused.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a perspective view of a lithography system, according to one embodiment.

FIG. 2 is a schematic view of an exemplary image projection system that may be used in lithography system of FIG. 1, according to one embodiment.

FIG. 3A is a top view of the substrate, according to one embodiment.

FIG. 3B shows a top view of a first pattern of radiation, according to one embodiment.

FIG. 3C shows a top view of a second pattern of radiation, according to one embodiment.

FIG. 4 is a process flow diagram of a method 1000 of modifying different areas of the photoresist layer on the substrate with different patterns of radiation, according to one embodiment.

FIG. 5A is a top view of the substrate, according to another embodiment.

FIG. 5B shows a top view of a first pattern of radiation, according to one embodiment.

FIG. 5C shows a top view of a second pattern of radiation, according to one embodiment.

FIG. 5D shows a top view of a third pattern of radiation and a fourth pattern of radiation, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to lithography systems and lithography methods. More specifically, embodiments described herein relate to lithography systems and methods for forming structures of varying dimensions (e.g., various depths) in less exposures, such as in a single pass.

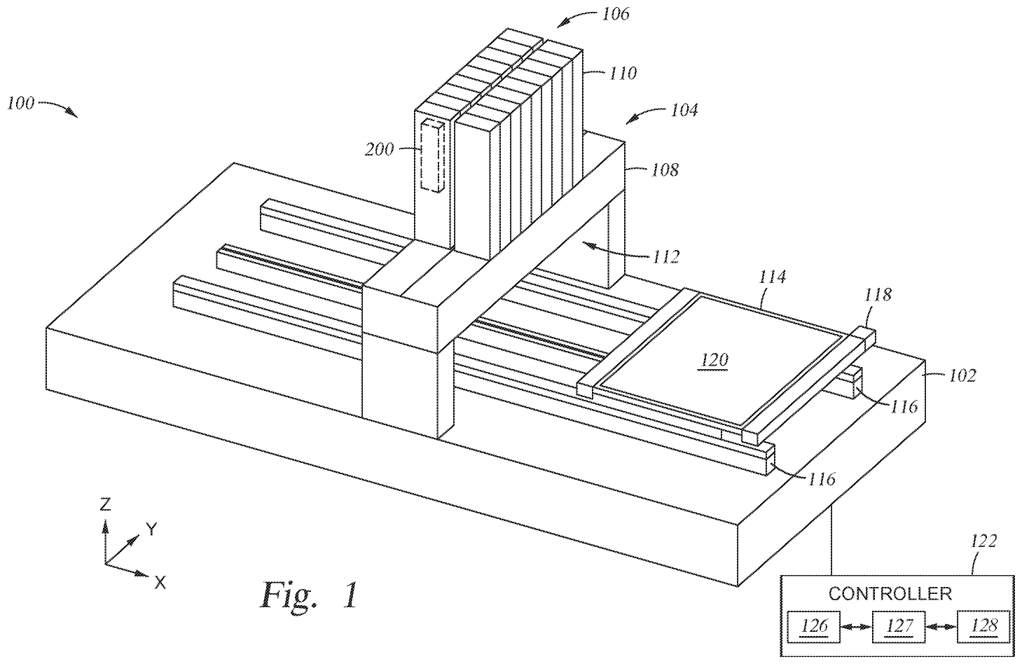

FIG. 1 is a perspective view of a lithography system 100, according to one embodiment. The lithography system 100 can be a digital lithography system. The lithography system 100 includes a processing apparatus 104, a stage 114, a slab 102, and a pair of tracks 116.

The stage 114 is supported by the pair of tracks 116 that are disposed on the slab 102. The stage 114 can be moved along the tracks 116 to different locations under the processing apparatus 104. A substrate 120 is positioned on the stage 114. A layer of photoresist can be disposed on the substrate 120. The processing apparatus 104 includes equipment for directing radiation (e.g., ultraviolet radiation) towards the photoresist on the substrate 120 when the substrate 120 is positioned below portions of the processing apparatus 104. Although the following disclosure describes forming structures by physically altering portions of a layer of photoresist (e.g., changing the solubility of the photoresist portions in relation to a photoresist developer), the benefits of this disclosure can apply to any layer that can be physically altered by any form of radiation.

The stage 114 is configured to move along the pair of tracks 116 in the X-direction as indicated by the coordinate system shown in FIG. 1. In one embodiment, which can be combined with other embodiments described herein, the pair of tracks 116 is a pair of parallel magnetic channels. As shown, each track of the pair of tracks 116 extends in a straight-line path.

The processing apparatus 104 includes a support 108 and a processing unit 106. The support 108 is disposed on the slab 102. The support 108 of the processing apparatus 104 straddles the pair of tracks 116 to form an opening 112. The processing unit 106 is supported over the slab 102 by the support 108. The pair of tracks 116 can extend through the opening 112. The opening 112 allows the stage 114 to be moved along the tracks 116 under the processing unit 106.

In one embodiment, which can be combined with other embodiments described herein, the processing unit 106 is a pattern generator configured to expose photoresist on the substrate 120 to radiation (e.g., UV radiation) in a photolithography process.

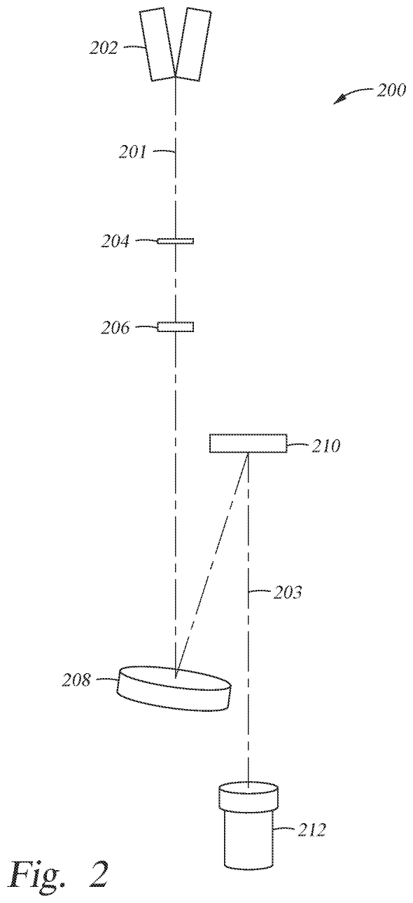

The processing unit 106 includes a plurality of image projection systems 200 that are each disposed in a case 110. Details on the image projection system 200 are discussed below in reference to FIG. 2. In FIG. 1, eighteen of the case 110 that house the image projection systems 200 are shown with each image projection system 200 disposed in one of the cases 110. Only one of the image projection systems 200 is shown in order to not clutter the drawing. In other embodiments, which can be combined with other embodiments described herein, the processing unit 106 can include less (e.g., five image projection systems 200) or more image projection systems (e.g., 50 image projection systems). The processing unit 106 is used to perform maskless direct pattern writing to photoresist or other electromagnetic radiation sensitive material.

The lithography system 100 further includes a controller 122 and an encoder 118. The controller 122 is generally designed to facilitate the automation of the processing methods described herein. The controller 122 can be any type of controller used in an industrial setting, such as a programmable logic controller (PLC). The controller 122 includes a processor 127, a memory 126, and input/output (I/O) circuits 128. The controller 122 can further include one or more of the following components (not shown), such as one or more power supplies, clocks, communication components (e.g., network interface card), and user interfaces typically found in controllers for semiconductor equipment.

The memory 126 can include non-transitory memory. The non-transitory memory can be used to store the programs and settings described below. The memory 126 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

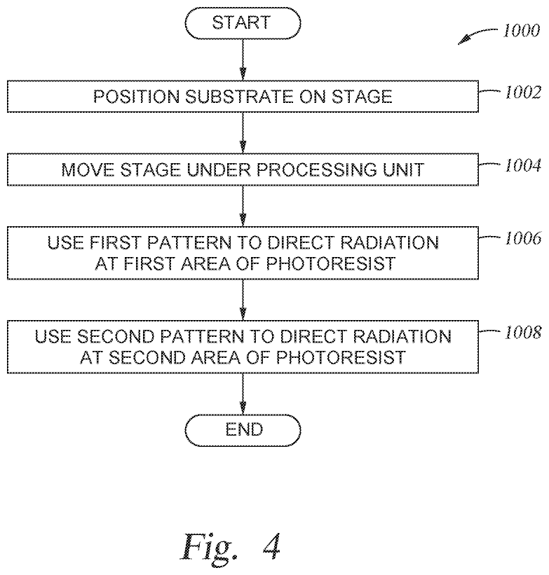

The processor 127 is configured to execute various programs stored in the memory 126, such as a program configured to execute the method 1000 described below in reference to FIG. 4. During execution of these programs, the controller 122 can communicate to I/O devices (e.g., processing apparatus 104, the stage 114 and the encoder 118) through the I/O circuits 128. For example, during execution of these programs and communication through the I/O circuits 128, the controller 122 can control outputs, for example to control the position of the stage 114 using information from feedback devices (e.g., encoder 118) and other inputs (e.g., sensors) in the lithography system 100. The memory 126 can further include various operational settings used to control the lithography system 100. For example, the settings can include pattern information for different patterns of radiation to be applied to one or more substrates. In some embodiments, the processing apparatus 104 can include a controller that can store information relating to the patterns to be applied to substrates for different processes.

The processing apparatus 104 may also provide information to the controller 122 regarding the status of the substrate processing. For example, the processing apparatus 104 may provide information to the controller 122 to alert the controller 122 that a portion of substrate processing has been completed. The controller 122 can also provide information to the processing apparatus 104, such as the position of the stage 114.

The encoder 118 can be coupled to the stage 114. The encoder 118 can be used to provide positional information of the stage 114 to the controller 122. The controller 122 can use this positional information to control the image projection systems 200 in the processing unit 106, so that specified portions of the photoresist on the substrate 120 can be exposed to a predetermined amount of radiation from the image projection system(s) 200, which enables the structures on the substrate 120 to be formed having the intended depth and shape.

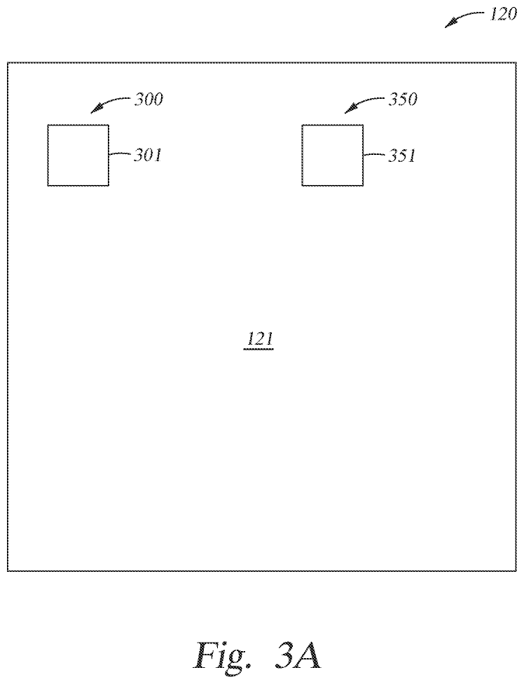

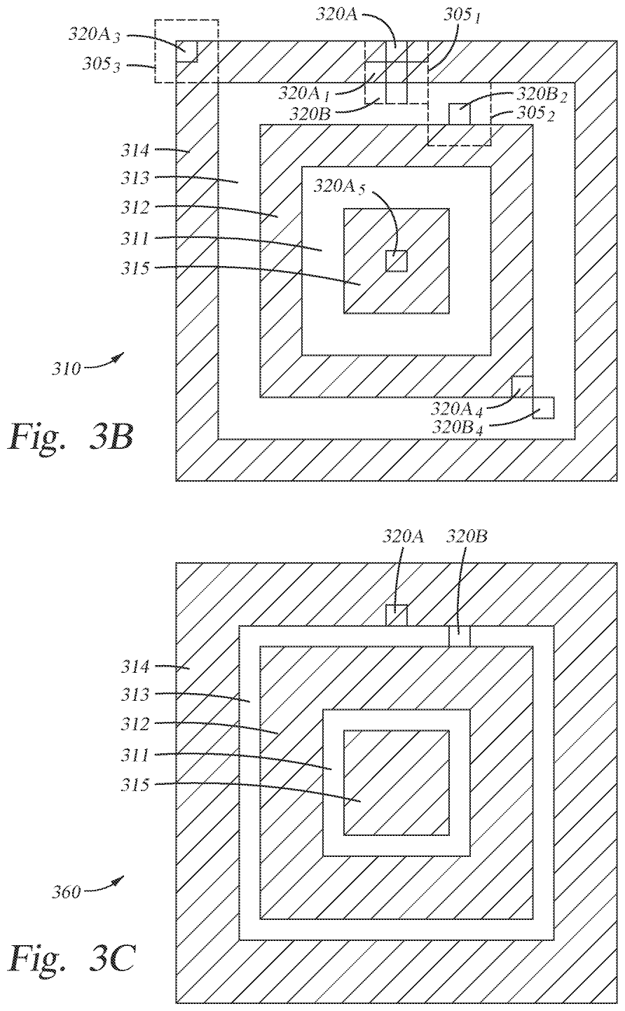

Programs (e.g., software instructions) stored in memory 126, which may be referred to as imaging programs, readable by the controller 122, determine which tasks are performable on a given substrate 120. These programs can include data relating to the patterns of radiation to be applied and code to monitor and control the processing time and substrate position during the process. The data relating to patterns of radiation (e.g., the first pattern 310 described below in reference to FIG. 3B) can correspond to a pattern to be written into the photoresist using the electromagnetic radiation provided from the image projection systems 200. This pattern data can also be referred to as mask pattern data due to how conventional lithography processes have used physical masks to perform lithography even though a physical mask is not used to perform the digital lithography processes described herein.

The controller 122 may further include a rasterizer to assist with converting patterns of radiation (e.g., the first pattern 310 described below in reference to FIG. 3B) stored in virtual mask files (e.g., image files) in the memory 126 to data that can be used by the image projection systems 200 to form the pattern stored in the virtual mask file on the photoresist layer on the substrate 120. The rasterizer can include a rasterizer computation engine which includes one or more field programmable gate arrays (FPGAs), graphics processing units (GPUs), a combination of FPGAs and GPUs.

Although the controller 122 is shown as a single component, this is not required. In some embodiments, the controller 122 can be distributed across multiple components of the lithography system 100. For example, the virtual mask files can be stored on a server, while a separate controller can be used to control the movement of the stage 114, and a separate controller can be used to direct the radiation from the image projection systems 200 at the photoresist layer on the substrate 120. The server and any separate controllers used can all each include non-transitory memory and processors to execute programs stored in the non-transitory memory, which enables the methods described below to be performed.

The substrate 120 can be formed of any suitable material including but not limited to silicon (Si), silicon dioxide (SiO2), fused silica, quartz, glass, silicon carbide (SiC), germanium (Ge), silicon germanium (SiGe), indium phosphide (InP), gallium arsenide (GaAs), gallium nitride (GaN), or sapphire. In some embodiments, which can be combined with other embodiments described herein, the substrate 120 is formed of other materials capable of being used as a part of a flat panel display.

A film layer (e.g., a film layer including chromium) can be formed on the substrate 120. A photoresist layer can be formed on the film layer. In some embodiments, the photoresist layer can be sensitive to electromagnetic radiation, for example UV or deep UV “light”. After exposure of the photoresist to the electromagnetic radiation, the photoresist is developed to leave a specified pattern.

FIG. 2 is a schematic view of an exemplary image projection system 200 that may be used in lithography system 100. As mentioned above in reference to FIG. 1, the processing unit 106 includes a plurality of image projection systems 200 each disposed in a case 110. Each image projection system 200 can provide radiation to different portions of the photoresist on the substrate 120. One of these image projection systems 200 is described here in reference to FIG. 2.

The image projection system 200 includes a light source 202, an aperture 204, a lens 206, a frustrated prism assembly 208, a spatial light modulator 210, and projection optics 212. The light source 202 can emit a light beam 201 at the lens 206 through the aperture 204. The lens 206 can direct the light beam 201 to the frustrated prism assembly 208, which can reflect the light to a plurality of mirrors on the spatial light modulator 210. The plurality of mirrors on the spatial light modulator 210 can each be individually controlled (e.g., electrically controlled) to be on or off. The mirrors that are in the “on” state for the spatial light modulator 210 can then reflect a plurality of write beams 203 through the projection optics 212 at different portions of the photoresist on the substrate 120.

In some embodiments, for example when the light source 202 is a laser, each beam 203 of the plurality of beams can include a multiplicity of shots. In some of these embodiments, the multiplicity of shots is separate pulses from the laser. In some of these embodiments, the multiplicity of shots can be a designated number of shots for each individual location at which a beam 203 is directed. For example, in some embodiments, the multiplicity of shots can be between about 50 to about 500 shots for each individual location (see e.g., portion 305 described below in reference to FIG. 3B). In other embodiments, the multiplicity of shots can be varied for different locations on the photoresist to enable another method of controlling the amount of radiation applied to each separate location on the photoresist.

The plurality of write beams 203 can physically alter the photoresist layer (first layer) on the substrate 120. For example, the radiation from the plurality of write beams 203 can change the solubility of the photoresist with respect to one or more photoresist developers. The mirrors in the “off” state for the spatial light modulator 210 can result in (1) corresponding portions of the photoresist not being exposed to the radiation or (2) corresponding portions of the photoresist being exposed to less radiation. As described in further detail below, patterns of radiation can be directed at the photoresist on the substrate 120 to form structures having different depths and/or shapes. When all other operation parameters for the radiation are held constant (e.g., radiation duration, power level, duty cycle, multiplicity of shots etc.), then the patterns of radiation with a higher ratio of “on” mirrors to total mirrors can generally physically alter the photoresist to greater depths than patterns of radiation with a lower ratio of “on” mirrors to total mirrors.

The light source 202 can be any suitable light source, such as a light emitting diode (LED) or a laser capable of producing one or more wavelengths. In one embodiment in which the light source 202 is a laser, which can be combined with other embodiments described herein, the wavelength emitted by the laser can be in the blue or near ultraviolet (UV) range, such as a wavelength less than about 450 nm.

The projection optics 212 can include projection lenses, for example 10× objective lenses, used to project the radiation onto the substrate 120.

In one embodiment, the spatial light modulator 210 is a digital micromirror device (DMD). Each mirror of the plurality of mirrors in the DMD can correspond to a unit cell (see e.g., unit cells 320 described below in reference to FIG. 3B) in the patterns described below. In some embodiments, which can be combined with other embodiments described herein, the DMD includes more than about 4,000,000 mirrors. Although the individually controllable elements used to direct the patterns of radiation are generally described in this disclosure as mirrors (e.g., digital micromirrors), these individually controllable elements can also include liquid crystal displays (LCDs), liquid crystal over silicon (LCoS) devices, ferroelectric liquid crystal on silicon (FLCoS) devices, and microshutters.

FIG. 3A is a top view of the substrate 120, according to one embodiment. In FIG. 3A, the substrate 120 includes a photoresist layer 121, a first modified portion 300 and a second modified portion 350. The modified portions 300, 350 are modified portions of the photoresist layer 121 (also referred to as first layer) on the substrate 120. The first modified portion 300 is formed by directing a first pattern 310 (see FIG. 3B) of radiation at a first area 301 of the photoresist layer 121. The second modified portion 350 is formed by directing a second pattern 360 (see FIG. 3C) of radiation at a second area 351 of the photoresist layer 121.

The modified portions 300, 350 are physically altered relative to unmodified portions of the photoresist layer 121. The modified portions 300, 350 are physically altered by the radiation directed at the corresponding first area 301 and second area 351. For example, the solubility of the photoresist layer 121 in the areas 301, 351 can be modified by the radiation to enable a photoresist developer to be applied to the substrate 120, so that structures (e.g., vias) can be formed from the modified portions 300, 350.

FIG. 3B shows a top view of a first pattern 310 of radiation, according to one embodiment. Radiation can be directed at the first area 301 according to the first pattern 310 of radiation to form the first modified portion 300 of FIG. 3A. Because portions in the first pattern 310 can correspond to portions of the first area 301, some parts of the first pattern 310 also referred to as parts of the first area 301 in the disclosure that follows. The hatched areas in the first pattern 310 identify corresponding portions in the first area 301 of photoresist 121 about which a beam of radiation (e.g., beam 203 in FIG. 2) is centrally focused on while the unhatched areas in the first pattern 310 identify corresponding portions in the first area 301 about which no beam of radiation is centrally focused. This concept of a beam of radiation being centrally focused on a particular area is explained in greater detail below.

The first pattern 310 includes a plurality of unit cells 320 to identify whether radiation is directed at and centrally focused on a particular location in a given area, such as the first area 301. The unit cells 320 include on cells 320A and off cells 320B. The hatched areas of the first pattern 310 include on cells 320A (a few of which are shown) that identify portions of the first area 301 that a beam of radiation is directed at and centrally focused on according to the first pattern 310. Conversely, the unhatched areas of the first pattern 310 include off cells 320B (a few of which are shown) that identify portions of the first area 301 that no beam of radiation is centrally focused on according to the first pattern 310.

The first pattern 310 is a ring-shaped pattern that includes groups of on cells 320A and off cells 320B arranged in concentric rings. The first pattern 310 includes a central portion 315 of on cells 320A. The central portion 315 is surrounded by a number of ring-shaped portions. A first ring-shaped portion 311 of off cells 320B is disposed around the central portion 315. A second ring-shaped portion 312 of on cells 320A is disposed around the first ring-shaped portion 311. A third ring-shaped portion 313 of off cells 320B is disposed around the second ring-shaped portion 312. A fourth ring-shaped portion 314 of on cells 320A is disposed around the third ring-shaped portion 313.

The first ring-shaped portion 311 is positioned between and contacts the central portion 315 and the second ring-shaped portion 312. The second ring-shaped portion 312 is positioned between and contacts the first ring-shaped portion 311 and the third ring-shaped portion 313. The third ring-shaped portion 313 is positioned between and contacts the second ring-shaped portion 312 and the fourth ring-shaped portion 314. The fourth portion 314 is the outermost portion of the first pattern 310.

The first pattern 310 is used to direct radiation at the first area 301 of FIG. 3A. The lithography system 100 (see FIG. 1) can be used to direct the radiation at the first area 301 (see FIG. 3A) according to the first pattern 310 (see FIG. 3B). For example, one or more of the image projection systems 200 (see FIG. 2) in the lithography system 100 can be used to direct the radiation at the first area 301. In one embodiment, the image projection system 200 can include an array of enough mirrors that can be electrically controlled to be in on an off states that correspond to all of the unit cells 320 in the first pattern 310, so that radiation is directed at the first area 301 from these separate mirrors in a geometric pattern that corresponds to the first pattern 310.

In another embodiment, the image projection system 200 can electrically control the mirrors to form the first pattern 310 over time. For example, in some embodiments a single mirror of one of the image projection systems 200 can be used to direct the corresponding beams of radiation for two or more of the on cells 320A in the first pattern 310. A single mirror can be used to direct corresponding beams of radiation for two or more on cells 320A in the first pattern by (1) using the stage 114 to move the substrate 120 and activating the mirror before and after movement of the stage, (2) changing the angle of the mirror so that the beam of radiation reflected from the mirror is directed at a different location on the substrate, and/or (3) changing the trajectory of a beam reflected from a mirror through other optical components in the lithography system 100 among other methods.

The beams of radiation applied to the first area 301 according to the first pattern 310 are larger than the components of the first pattern 310 (i.e., larger than the unit cells 320 that make up the hatched areas and the unhatched areas of the first pattern 310). For example, when a beam of radiation is applied to the first area 301 based on a first unit cell 320A₁, a single beam of radiation is incident upon a portion 305₁ of the first area 301. The portion 305₁ extends from a hatched part in the fourth portion 314 and into an unhatched part in the third portion 313 of the first pattern 310 and first area 301. Thus, radiation can still be directed at parts of the first area 301 that correspond to unhatched areas of the first pattern 310. This is because the unhatched parts of the first pattern 310 only indicate that no beam of radiation is centrally focused on these parts of the first area 301 that correspond to unhatched areas of the first pattern 310. For example, no beam of radiation is directed at the first area 301 to be centrally focused on the off cell 320B₂ in a portion 305₂ of the first area 301 because the off cell 320B₂ is in an unhatched part of the first pattern 310.

Although only a few unit cells 320 are shown in FIG. 3B in order to not clutter the drawing, the unit cells 320 would fill the entire first pattern 310, for example in a non-overlapping arrangement, if all were shown. In one embodiment, as shown in FIG. 3B, the plurality of unit cells 320 can be arranged in a two-dimensional array (e.g., a gird). In some embodiments, although not required, each unit cell 320 in the plurality of unit cells 320 can have a same size (e.g., all squares of a same size). The area of each unit cell 320 can be smaller than the area of the portions 305. For example, in FIG. 3B the unit cells 320 have an area that is one ninth the area of the portions 305 as nine unit cells 320 can fit inside and fill each portion 305. In other embodiments, the unit cells 320 can have areas that are smaller than the area of the portions 305 by a greater or lesser degree than one ninth.

Once an area, such as the first area 301, is selected to receive the first pattern 310 of radiation, the unit cells 320 in the first pattern 310 correspond to locations in the first area 301. For example, once the first area 301 is selected to receive radiation according to the first pattern 310, a top left corner unit cell 320A₃ of the first pattern 310 can correspond to the radiation that a top left portion 305₃ will receive when radiation is applied according to the location of unit cell 320A₃ in the first pattern 310. Note that the radiation applied to the first area 301 is larger than the first pattern 310 because the radiation beam applied is larger than the unit cells 320. For example, as shown by the top left corner portion 305₃, the first area 301 is larger than the first pattern 310 by one unit cell 320 on all four sides of the first pattern 310.

Because the beams of radiation are incident upon portions 305 in the first area 301 that are larger than the unit cells 320, the portions 305 of the first area 301 on which the beams of radiation are incident upon overlap. The amount of overlap depends on the area of the unit cell 320 compared to the area of the portion 305. As shown in portion 305₁, nine unit cells 320 can fit inside and fully fill one portion 305. The greater the number of unit cells 320 in a portion 305, the greater the number of beams that can be incident upon a given location in the first area 301 when the radiation from different on cells 320A overlap in a single area. For example, if a portion 305 were entirely filled with nine hatched unit cells 320A, then the center location of that portion 305 (i.e., a location the size of a unit cell 320) would receive nine different beams of overlapping radiation when radiation is applied according to the pattern.

Thus, if each location in the first area 301 receives at least one beam of radiation, the locations in the area 301 can vary from receiving one beam of radiation to nine beams of radiation. For example, the location of the photoresist 121 that corresponds to the area enclosed by the off cell 320B₄ would only receive one beam of radiation when the radiation is applied according to the on cell 320A₄. Conversely, the centrally located area of photoresist 321 that corresponds to area enclosed by the on cell 320A₅ would receive nine overlapping beams of radiation when the radiation is applied according to the on cell 320A₅ and then applied according to the eight on cells 320A (not shown) that surround the on cell 320A₅.

The percentages of on cells 320A out of the total number of unit cells in a given pattern (e.g., the first pattern 310) can vary substantially. When holding other factors constant with respect to the radiation applied to a same layer of photoresist, a pattern with a higher percentage of on cells 320A can generally result in photoresist that is be modified to a deeper depth relative to patterns including a lower percentage of on cells 320A when the radiation is applied according to the respective patterns. While the percentage of on cells 320A out of a total number of unit cells 320 can be any number between 0% and 100%, some non-limiting examples of percentages of on cells 320A out of a total number of unit cells 320 that may be used in a pattern include a percent from about 25% to about 50%, a percent from about 50% to about 75%, a percent from about 75% to about 95%.

Although all of the entire first area 301 is exposed to radiation, all of the first area 301 is not exposed to the same amount of radiation. The first pattern 310 is used to control how much radiation different portions of the photoresist 121 in the first area 301 receive. For example, the first portion 311 and the third portion 313 of the first pattern 310, which are occupied by a plurality of off cells 320B, reduce the amount of radiation that would otherwise be received by the first area 301 if the first pattern 310 only included on cells 320A. The percentage of off cells 320B out of the total number of unit cells 320 in a radiation pattern (e.g., the first pattern 310) can be used as a method for controlling how much radiation an area (e.g., the first area 301) receives. Furthermore, the placement of the off cells 320B in a radiation pattern can be used as a method for controlling how much radiation a particular portion of an area receives relative to other portions of the area.

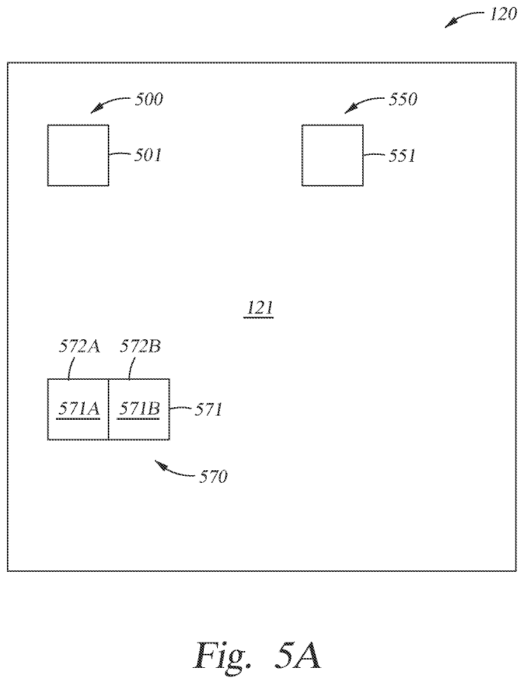

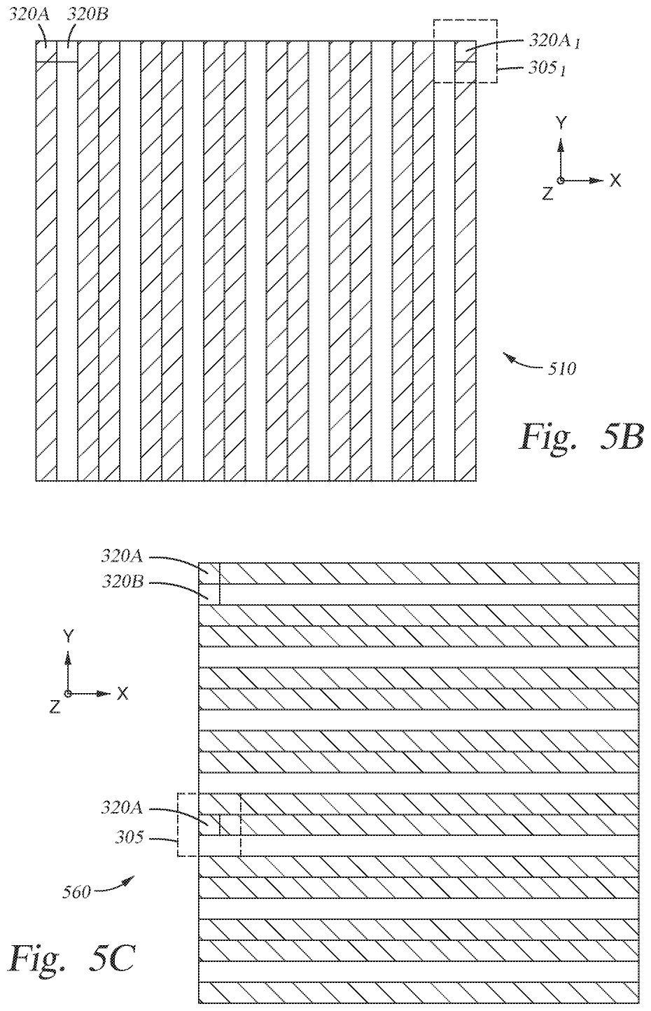

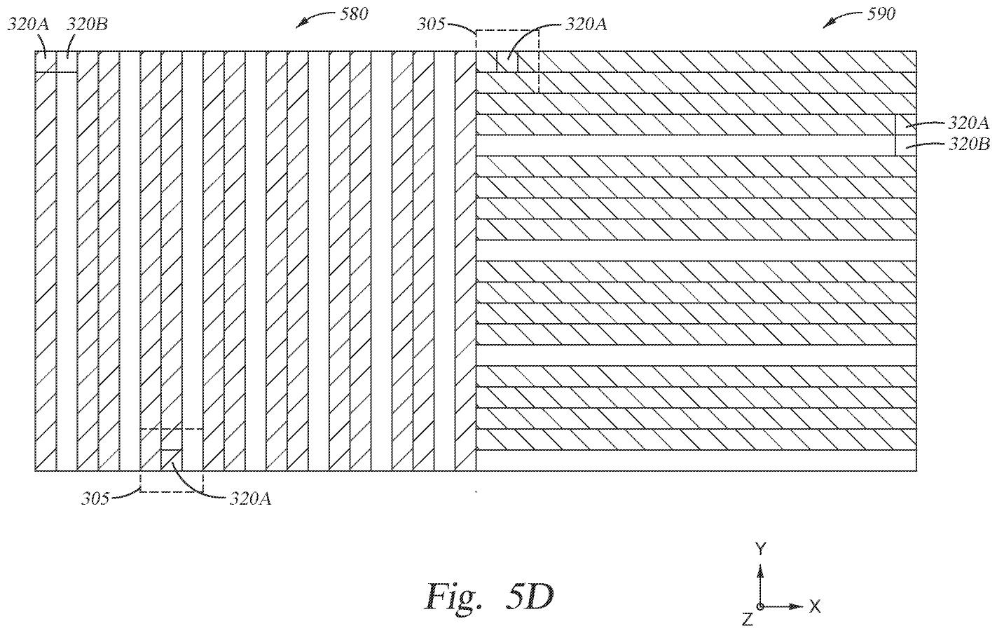

The amount of radiation a particular portion of photoresist receives is related to how much that particular portion of photoresist ends up being modified by the radiation. For example, portions of photoresist receiving greater amounts of radiation are generally modified to greater depths than other portions of photoresist receiving less radiation. Thus, radiation patterns (e.g., the first pattern 310) can be used to control the depth at which photoresist is modified in a given area (e.g., the first area 301) as well as modify the depth at which photoresist is modified across a given area (see description of FIG. 5 discussed below). Furthermore, different patterns of radiation can be used to form areas that have photoresist modified to different depths, which ultimately allows structures (e.g., vias) of different depths and/or shapes to be formed on a substrate. One example of a different pattern of radiation is described below in reference to FIG. 3C.

FIG. 3C shows a top view of a second pattern 360 of radiation, according to one embodiment. Radiation can be directed at the second area 351 according to the second pattern 360 of radiation to form the second modified portion 350 of photoresist 121 as shown in FIG. 3A. Because portions in the second pattern 360 can correspond to portions of the second area 351, some parts of the second pattern 360 are also referred to as parts of the second area 351.

The second pattern 360 of radiation is the same as the first pattern 310 of radiation except that the ring-shaped portions 311-314 have different sizes in the second pattern 360 relative to the first pattern 310. For example, the first portion 311 and the third portion 313 of off cells 320B are smaller in the second pattern 360 compared to the corresponding portions 311, 313 in the first pattern 310. Additionally, the second portion 312 and the fourth portion 314 of the on cells 320A are larger in the second pattern 360 compared to the corresponding portions 312, 314 in the first pattern 310. Thus, the second pattern 360 includes a higher percentage of on cells 320A out of the total number of unit cells 320 in second pattern 360 compared to the first pattern 310.

Because the second pattern 360 includes a higher percentage of on cells 320A compared to the first pattern 310, when all other operation parameters for the radiation are held constant (e.g., radiation intensity, duration, multiplicity of shots, duty cycle, etc.) when both patterns 310, 360 of radiation are applied, then there is a greater amount of radiation directed towards portions of the second area 351 when the second pattern 360 is used relative to when the first pattern 310 is used. This greater amount of radiation directed towards the second area 351 can cause portions of the photoresist in the modified portion 350 to be modified to a greater depth than the photoresist in the modified portion 300. Thus, the different patterns 310, 360 show how different areas of photoresist can be modified to different depths, which ultimately allows structures (e.g., vias) of different depths and/or shapes and different to be formed. Depending on the patterns, different patterns of radiation applied to different areas of photoresist can result in the modified portions of the photoresist having different maximum depths and/or different depths across corresponding portions of the areas.

Patterns of radiation can also be tailored to form structures of different shapes. For example, radiation can be reduced towards the edge of a pattern to create a sidewall of a structure with less of a slope. Conversely, using a pattern that calls for substantially constant radiation from center to edge or a pattern that calls for a greater amount of radiation at the edge relative to the center can make a steeper sidewall for the structure being formed by the radiation.

FIG. 4 is a process flow diagram of a method 1000 of modifying different areas of the photoresist layer 121 on the substrate 120 with different patterns of radiation, according to one embodiment. The method 1000 is described in reference to FIGS. 1-3C. The controller 122 (see FIG. 1) can execute a program stored in memory to perform some or all of the method 1000. The method 1000 begins at block 1002.

At block 1002, the substrate 120 is positioned on the stage 114.

At block 1004, the stage 114 is moved under the processing unit 106, so that one or more of the image projection systems 200 can direct radiation towards the photoresist layer 121 on the substrate 120.

At block 1006, the first pattern 310 is used to direct a first plurality of beams of radiation at the first area 301 of the photoresist 121 on the substrate 120 to form the first modified portion 300. The plurality of mirrors in one or more of the spatial light modulators 210 can be used to form the plurality of on cells 320A and the plurality of off cells 320B in the first pattern 310, so that the first plurality of beams of radiation can be directed to the first area 301 according to the first pattern 310. In some embodiments, there is enough mirrors in the spatial light modulator 210, so that a separate mirror can be used for each unit cell 320 in the first pattern 310. In other embodiments, some of the mirrors in the spatial light modulator 210 can be reused for two or more unit cells 320 in the pattern as the stage 114 moves the substrate 120 to different locations enabling these mirrors over time to generate the first pattern 310 as the stage 114 is moved. In some embodiments, an angle of some of the mirrors in the spatial light modulator can be adjusted enabling these mirrors to be used for two or more unit cells 320 in the first pattern 310.

At block 1008, the second pattern 360 is used to direct a second plurality of beams of radiation at the second area 351 of the photoresist 121 on the substrate 120 to form the second modified portion 350. The plurality of mirrors in one or more of the spatial light modulators 210 can be used to form the plurality of on cells 320A and the plurality of off cells 320B in the second pattern 360, so that the radiation can be directed to the second area 351 according to the second pattern 360. In some embodiments, there is enough mirrors in the spatial light modulator 210, so that a separate mirror can be used for each unit cell 320 in the second pattern 360. In other embodiments, some of the mirrors in the spatial light modulator 210 can be reused using similar methods as described above in reference to block 1006. In some embodiments, blocks 1006, 1008 are performed at separate times while in other embodiments, blocks 1006, 1008 can be performed simultaneously.

As mentioned above, the second pattern 360 has a higher percentage of on cells 320A relative to the first pattern 310. This higher ratio results in the photoresist 121 being modified (e.g., solubility of the photoresist with respect to a photoresist developer changes) to a deeper depth in parts of the second portion 350 relative to corresponding parts of the first modified portion 300 when the same amount and type of radiation is emitted from each on cell 320A in the respective patterns 310, 360. Although only two patterns 310, 360 of radiation are directed at the substrate 120 during the method 1000, the method 1000 can be continued to direct radiation using additional patterns (not shown) or the same patterns 310, 360 at other areas of the photoresist 121, so that other structures of various depths and/or shapes can be formed.

The method 1000 can also be executed on two or more regions of a single area, so that different patterns of radiation can be applied to two or more regions of a single area, so that the depth and/or shape of modified photoresist can be adjusted across the single area. An example of applying two different patterns of radiation to two regions in a single area is described in greater detail below in reference to FIG. 5D.

FIG. 5A is a top view of the substrate 120, according to another embodiment. In FIG. 5A, the substrate 120 includes the photoresist layer 121, a first modified portion 500, a second modified portion 550, and a third modified portion 570. The modified portions 500, 550, 570 are modified portions of the photoresist layer 121 (also referred to as first layer) on the substrate 120. The first modified portion 500 is formed by directing a first pattern 510 (see FIG. 5B) of radiation at a first area 501 of the photoresist layer 121. The second modified portion 550 is formed by directing a second pattern 560 (see FIG. 5C) of radiation at a second area 551 of the photoresist layer 121. The third modified portion 570 is formed by directing a third pattern 580 of radiation at a first region 571A of a third area 571 of the photoresist layer 121 and a fourth pattern 590 (see FIG. 5D) of radiation at a second region 571B of the third area 571 of the photoresist layer 121.

The modified portions 500, 550, 570 are physically altered relative to unmodified portions of the photoresist layer 121. The modified portions 500, 550, 570 are physically altered by the radiation directed at the corresponding first area 501, second area 551, and third area 571. For example, the solubility of the photoresist layer 121 in the areas 501, 551, 571 can be modified by the radiation to enable a photoresist developer to be applied to the substrate 120, so that structures (e.g., vias) can be formed from the modified portions 500, 550, 570.

FIG. 5B shows a top view of a first pattern 510 of radiation, according to one embodiment. Radiation can be directed at the first area 501 according to the first pattern 510 of radiation to form the first modified portion 500 of FIG. 5A. Because portions in the first pattern 510 can correspond to portions of the first area 501, some parts of the first pattern 510 are also referred to as parts of the first area 501.

The first pattern 510 of radiation is similar to the patterns 310, 360 described above in reference to FIGS. 3B and 3C except that the arrangement of on cells 320A and off cells 320B is different. Although not required, the unit cells 320 can have a same size in the first pattern 510 as the unit cells 320 in the patterns 310, 360. Furthermore, although not required each beam of radiation applied according to the first pattern 510 can be incident upon a portion 305 having a same size as the portions 305 described above in reference to FIGS. 3B and 3C. An exemplary portion 305₁ is shown in the top right corner of the first pattern 510 in which the portion 305₁ is centrally focused on an on cell 320A₁.

In the first pattern 510, the hatched areas include and are fully filled by the on cells 320A while the unhatched areas include and are fully filled by the off cells 320B. The on cells 320A are arranged in columns extending in the Y-direction. Similarly, the off cells 320B are arranged in columns extending in the Y-direction. Arranging the on cells 320A in a column, positions a plurality of the on cells 320A along a line that includes consecutive on cells 320A without any intervening off cells 320B. Arranging the off cells 320B in a column also positions a plurality of the off cells 320B along a line that includes consecutive off cells 320B without any intervening off cells 320A.

Using patterns with groupings of consecutive on cells 320A and consecutive off cells 320B can help increase the processing speed of applying a pattern of a radiation to a substrate. The use of consecutive on cells 320A and consecutive off cells 320B can reduce the processing demands on components of the lithography system 100, such as a rasterizer. When patterns are used without large groupings of consecutive on cells 320A or off cells 320B (e.g., a checkerboard pattern), then the processing speed of applying the pattern of radiation is often slower than the processing speed of applying a pattern of radiation with more groupings of consecutive on cells 320A and consecutive off cells 320B, such as the patterns 510, 560, 580, and 590 described in reference to FIGS. 5B-5D.

Although all of the on cells 320A and all of the off cells 320B are included in lines of consecutive on cells 320A and off cells 320B, this is not required to obtain increases in processing speed. Increasing the percentage (e.g., 25%, 50%, 75%, 90%, 95%, 99% or higher) of on cells 320A and/or off cells 320B that are in corresponding lines of consecutive on cells 320A and off cells 320B can increase processing speed. Similarly, increasing the number of consecutive on cells 320A and consecutive off cells 320B (e.g., at least ten consecutive cells, at least 50 consecutive cells, at least 100 consecutive cells, at least 250 consecutive cells, at least 500 consecutive cells, at least 1000 consecutive cells) that are in these lines of consecutive unit cells 320 can also increase the processing speed.

FIG. 5C shows a top view of a second pattern 560 of radiation, according to one embodiment. Radiation can be directed at the second area 551 according to the second pattern 560 of radiation to form the second modified portion 550 of FIG. 5A. Because portions in the second pattern 560 can correspond to portions of the second area 551, some parts of the second pattern 560 are also referred to as parts of the second area 551.

The second pattern 560 of radiation is the same as the first pattern 510 of radiation except that the second pattern 560 of radiation includes consecutive on cells 320A and consecutive off cells 320B that are arranged in rows extending in the X-direction as opposed to the columns extending in the Y-direction described above in reference to FIG. 5B. Arranging the lines of consecutive unit cells 320 in rows as opposed to columns can be useful depending on the type of equipment (e.g., lithography system 100) being used, the substrate being used, or the position of the area that is to receive the pattern of radiation on a given substrate. For example, with some equipment it may be more beneficial for reducing processing time for applying a pattern of radiation to have the lines of consecutive unit cells 320 be parallel or perpendicular to the movement of the substrate support (e.g., the stage 114).

Other arrangements of consecutive on cells 320A and consecutive off cells 320B may also be useful. For example, in one embodiment consecutive on cells 320A and consecutive off cells 320B can be arranged along diagonal lines (e.g., a 45 degrees diagonal line or any angle than straight or perpendicular) of consecutive on cells 320A and consecutive off cells 320B. The lines can be diagonal relative to the edges of the pattern (e.g., edge of the first pattern 510 shown in FIG. 5B), edges of features that are printed on the substrate, or the edges of the substrate (e.g., edges of the rectangular substrate 120 shown in FIG. 1A). For example, using diagonal lines of consecutive on cells 320A and consecutive off cells 320B that are diagonal with respect to the features that are printed on the substrate can in some instances produce a better product (i.e., the patterns on the product may be less noticeable to users of the end product, such as display on an electronic device). A random pattern of on cells 320A and off cells 320B may also be beneficial for producing a better product (i.e., the patterns on the product may be less noticeable to users of the end product, such as display on an electronic device).

FIG. 5D shows a top view of a third pattern 580 of radiation and a fourth pattern 590 of radiation, according to one embodiment. Radiation can be directed at the third area 571 according to the third pattern 580 and the fourth pattern 590 of radiation to form the third modified portion 570 of FIG. 5A. Because portions in the third pattern 580 and the fourth pattern 590 can correspond to portions of the third area 571, some parts of the third pattern 580 and the fourth pattern 590 are also referred to as parts of the third area 571. Like the patterns described above, the hatched areas of the patterns 580, 590 can include and be completely filled in by on cells 320A while the unhatched areas of the patterns 580, 590 can include and be completely filled in by off cells 320B. Furthermore, each on cell 320A in the patterns 580, 590 can identify a portion 305 around which radiation is centrally focused according to the respective pattern.

The patterns in FIG. 5D provide an example of how two patterns 580, 590 of radiation can be directed at single area 571. Directing two or more patterns at a single area (e.g., third area 571) can be used to vary the depth at which portions of the photoresist 121 is modified across the single area. For example, because the fourth pattern 590 includes a higher percentage of hatched areas (i.e., the areas that identify portions where a beam of radiation is centrally focused on) than the third pattern 580, portions of the photoresist 121 in the second region 571B can be modified to a deeper depth than the photoresist 121 in the first region 571A.

Directing two or more patterns at a single area (e.g., third area 571) can also be used to vary the shape of the portions of photoresist 121 that are modified. For example, the first region 571A includes a sidewall 572A that is connected to a sidewall 572B of the second region 571B. The top row of unit cells of the third pattern 580 corresponds to some of the radiation directed at the section of the first region 571A that includes the sidewall 572A. This top row of the third pattern 580 includes seven off cells 320B. On the other hand, a corresponding top row in the fourth pattern 590 corresponding to some of the radiation directed at this top section of the second region 571B that includes the sidewall 572B includes zero off cells 320B. Because this top section in the fourth pattern 590 has fewer off cells 320B than the corresponding section in the third pattern 580, the top section of the second region 571B can receive more radiation than the corresponding section in the first region 571A. In some embodiments, this increased radiation in the top portion of the second region 571B relative to the top portion of the first region 571A can cause the sidewall 572B to have a steeper slope than the sidewall 572A.

For all of the patterns of radiation described herein, at least some of the off cells 320B are positioned between some of the on cells 320A. This positioning off the off cells 320B between some of the on cells 320A enables the radiation to be modified within the pattern, which enables the control of the depth and shape of the photoresist that is modified by the radiation.

Although the description of the patterns described above have described using unit cells 320 of a same size, it is also possible to adjust the size of the unit cell 320 for different patterns of radiation on one or more substrates or within a single pattern on a substrate. For example, unit cells having a larger area can be used on portions where there is less change in the shape and/or depth of the structures being formed by the radiation. On the other hand, unit cells having a smaller area can be used more change in the shape and/or depth of the structures being formed by the radiation. Using unit cells having a smaller can allow for more precise control of the structures being formed. Conversely, larger unit cells can reduce the processing time as the number of beams directed at the substrate is directly related to the number of unit cells and thus inversely related to the size (i.e., area) of unit cells that do not overlap.

Additionally, the size of the portions (see e.g., portion 305 in FIG. 3B) on which radiation is directed can also be adjusted for different patterns of radiation on one or more substrates or within a single pattern on a substrate. Larger portions can be used to reduce processing time while smaller portions can allow for more precise control over the depth and shape of the structures being formed by the radiation.

The embodiments described above, provide a system and methods forming structures of different depths and shapes in a single exposure (i.e., a single pass of the substrate under the processing unit 106 shown in FIG. 1). The image projection systems 200 in the processing unit 106 can direct the overlapping portions 305 of radiation at the photoresist 121 according to the patterns being applied (e.g., the first pattern 310 in FIG. 3B). The overlapping portions of radiation are directed according to the layout of the on cells 320A and off cells 320B in the pattern being applied. Each beam of radiation applied is centrally focused on an area of photoresist corresponding to one of the on cells 320A in the pattern being applied. The size of the unit cells 320 are smaller than the size of the radiation being applied, which enables precise control over the amount of radiation being applied to each unit cell sized area of the photoresist as described above. This precise control allows the depth and shape of the structures being formed by the radiation to be finely controlled and completed in a single pass of the substrate under the lithography system.

To form structures having different depths and shapes using conventional lithography systems with conventional masks, multiple passes of the substrate under the writable area of the lithography system are required. Multiple passes of the substrate under the writable area of the lithography system decreases throughput. Therefore, the system and methods described above which allow structures of different depths and/or shapes to be formed in a single pass of the substrate offer a significant improvement over techniques using conventional lithography systems.

While the foregoing is directed to examples of the present disclosure, other and further examples of the disclosure may be devised without departing from the basic scope thereof, and the scope thereof is determined by the claims that follow.

What is claimed is:

1. A method, comprising:
directing a plurality of beams of radiation at a first area of a first layer on a substrate, each beam incident upon a different portion of a plurality of portions within the first area, wherein
each portion has an area of a first size,
the plurality of beams of radiation are directed at the first area based on a first pattern,
the first pattern comprises a plurality of unit cells that include a plurality of on cells and a plurality of off cells,
each unit cell has an area smaller than the first size,
the plurality of on cells identify locations within the first area at which a beam of radiation of the plurality of beams of radiation is centrally focused, and
the plurality of off cells identify locations within the first area at which no beam of radiation of the plurality of beams of radiation is centrally focused.

2. The method of claim 1, wherein at least some of the off cells in the first pattern are positioned between some of the on cells in the first pattern.

3. The method of claim 1, wherein all of the first area is irradiated by at least some of the plurality of beams of radiation.

4. The method of claim 1, wherein the first layer is a layer of photoresist.

5. The method of claim 1, wherein a percentage of on cells in the first pattern is from about 75% to about 95% out of a total number of unit cells in the first pattern.

6. The method of claim 1, wherein a percentage of on cells in the first pattern is from about 50% to about 75% out of a total number of unit cells in the first pattern.

7. The method of claim 1, wherein a percentage of on cells in the first pattern is from about 25% to about 50% out of a total number of unit cells in the first pattern.

8. The method of claim 1, wherein at least 75% of the on cells are positioned in the first pattern along a line that includes at least ten consecutive on cells.

9. The method of claim 8, wherein at least 75% of the off cells are positioned in the first pattern along a line that includes at least ten consecutive off cells.

10. A method, comprising:
directing a first plurality of beams of radiation at a first area of a first layer on a substrate, each beam incident upon a different portion of a plurality of portions within the first area; and
directing a second plurality of beams of radiation at a second area of the first layer on the substrate, each beam incident upon a different portion of a plurality of portions within the second area, wherein
each portion in the first area and the second area has an area of a first size,
the first plurality of beams of radiation are directed at the first area based on a first pattern,
the second plurality of beams of radiation are directed at the second area based on a second pattern,
the first pattern and the second pattern each comprise a plurality of unit cells that each include a plurality of on cells and a plurality of off cells,
each unit cell in the first pattern and the second pattern has an area smaller than the first size,
the plurality of on cells in the first pattern identify locations within the first area at which a beam of radiation of the first plurality of beams of radiation is centrally focused,
the plurality of off cells in the first pattern identify locations within the first area at which no beam of radiation of the first plurality of beams of radiation is centrally focused,
the plurality of on cells in the second pattern identify locations within the second area at which a beam of radiation of the second plurality of beams of radiation is centrally focused, and
the plurality of off cells in the second pattern identify locations within the second area at which no beam of radiation of the second plurality of beams of radiation is centrally focused.

11. The method of claim 10, wherein the first pattern includes a different arrangement of on cells and off cells than the second pattern.

12. The method of claim 10, wherein
the first pattern includes a first percentage of on cells out of a total number of unit cells in the first pattern,
the second pattern includes a second percentage of on cells out of a total number of unit cells in the second pattern, and
the first percentage is different than the second percentage.

13. The method of claim 10, wherein the first layer is a photoresist layer.

14. The method of claim 13, wherein the photoresist layer in the first area is physically altered to a maximum depth that is different than a maximum depth at which the photoresist layer in the second area is physically altered.

15. The method of claim 10, wherein the first area is larger than the second area.

16. The method of claim 10, wherein, for the first pattern and the second pattern, at least some of the off cells are positioned between some of the on cells.

17. A method, comprising:
directing a first plurality of beams of radiation at a first region of a first area of a first layer on a substrate, each beam in the first plurality of beams incident upon a different portion of a plurality of portions within the first region; and
directing a second plurality of beams of radiation at a second region of the first area, each beam of the second plurality of beams incident upon a different portion of a plurality of portions within the second region, wherein
each portion in the first region and the second region has an area of a first size,
the second plurality of beams of radiation are directed at the first region of the first area based on a first pattern,
the second plurality of beams of radiation are directed at the second region of the first area based on a second pattern,
the first pattern and the second pattern each comprise a plurality of unit cells that include a plurality of on cells and a plurality of off cells,
each unit cell in the first pattern and the second pattern has an area smaller than the first size,
the plurality of on cells in the first pattern identify locations within the first region at which a beam of radiation of the first plurality of beams of radiation is centrally focused,
the plurality of off cells in the first pattern identify locations within the first region at which no beam of radiation of the first plurality of beams of radiation is centrally focused,
the plurality of on cells in the second pattern identify locations within a second region at which a beam of radiation of the plurality of beams of radiation is centrally focused, and
the plurality of off cells in the second pattern identify locations within the second region at which no beam of radiation of the second plurality of beams of radiation is centrally focused.

18. The method of claim 17, wherein for the first region and the second region, at least some of the off cells are positioned between some of the on cells.

19. The method of claim 17, wherein all of the first area is irradiated by at least some of the first plurality of beams of radiation or the second plurality of beams of radiation.

20. The method of claim 17, wherein the first layer is a layer of photoresist.
